(19) United States
(12) Patent Application Publication
(10) Pub. No.: US 2010/0093142 A1
(43) Pub. Date: Apr. 15, 2010

(54) METHOD OF FABRICATING DEVICE

(75) Inventors: Ching-Yuan Ho, Tainan City (TW); Hirotake Fujita, Hsinchu County (TW); Po-Jui Chiang, Changhua County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 12/248,049

(22) Filed: Oct. 9, 2008

(51) Int. Cl. H01L 21/336; H01L 21/314

(52) U.S. Cl. 438/261; 438/762; 257/E21.423; 257/E21.422; 257/E21.267

(57) ABSTRACT

A method of fabricating a device is described. A substrate having at least two isolation structures is provided. A first oxide layer and a first conductive layer are sequentially formed on the substrate between the isolation structures. A first nitridation process is performed to form a first nitride layer on the surface of the first conductive layer and a first oxynitride layer on the surface of the isolation structures. A second oxide layer is formed on the first nitride layer and first oxynitride layer. A densification process is performed to oxidize the first oxynitride layer on the surface of the isolation structures. A second nitride layer and a third oxide layer are sequentially formed on the second oxide layer. A second nitridation process is performed to form a third nitride layer on the surface of the third oxide layer. A second conductive layer is formed on the third nitride layer.

### BACKGROUND OF THE INVENTION

1. Field of Invention

The present invention relates to a method of fabricating a semiconductor, and more generally to a method of fabricating a device.

2. Description of Related Art

A non-volatile memory provides the property of multiple entries, retrievals and erasures of data, and is able to retain the stored information even when the electrical power is off. As a result, a non-volatile memory is widely used in personal computers and consumer electronic products.

A typical non-volatile memory has a stacked-gate structure, which includes a tunnel dielectric layer, a floating gate, an inter-gate dielectric layer and a control gate sequentially formed on a substrate. As the dimension of a non-volatile memory is getting smaller, how to keep a certain gate coupling ratio (GCR) has become one of the main topics. To achieve the purpose of keeping a certain gate coupling ratio, it is known to thin the tunnel dielectric layer or the inter-gate dielectric layer. However, the process of reducing the thickness of the tunnel dielectric layer is hard to control, so that manufacturers tend to reduce the thickness of the inter-gate dielectric layer instead.

The leakage current may increase as the inter-gate dielectric layer becomes thinner. Accordingly, after the step of forming the floating gate and before the step of forming the inter-gate dielectric layer, it is known to perform a nitirdation process, so as to increase the dielectric constant k and the gate coupling ratio at the same effective oxide thickness (EOT) of the inter-gate dielectric layer.

However, during the nitridation process, an oxynitride layer is formed on the surface of the isolation structures beside the stacked-gate structure, so that a leakage path is faulted, and in the memory array, currents flow from one floating gate to the adjacent floating gates via the oxynitride layer on the surface of the isolation structures. Thus, the reliability and the charge retention ability are reduced, and the operation speed of the device is affected.

### SUMMARY OF THE INVENTION

Accordingly, the present invention provides a method of fabricating a device, with which a leakage problem is avoided under the condition of enhancing the gate coupling ratio.

The present invention further provides a method of fabricating a device, with which the reliability and the charge retention ability are enhanced, and the operation speed of the device is increased.

The present invention provides a method of fabricating a device. First, a substrate having at least two isolation structures is provided. Thereafter, a first oxide layer and a first conductive layer are sequentially formed on the substrate between the isolation structures. Afterwards, a first nitridation process is performed, so as to form a first nitride layer on the surface of the first conductive layer and a first oxynitride layer on the surface of the isolation structures. A second oxide layer is then formed on the first nitride layer and the first oxynitride layer. Further, a densification process is performed, so as to oxidize the first oxynitride layer on the surface of the isolation structures. Thereafter, a second nitride layer is formed on the second oxide layer. Afterwards, a third oxide layer is formed on the second nitride layer. Further, a second nitridation process is performed, so as to form a third nitride layer on the surface of the third oxide layer. A second conductive layer is then formed on the third nitride layer.

According to an embodiment of the present invention, the first conductive layer includes polysilicon, for example.

According to an embodiment of the present invention, the first nitridation process and the second nitridation process include using remote plasma nitridation, decoupled plasma nitridation or microwave radical generator to generate nitrogen free radicals.

According to an embodiment of the present invention, the densification process includes a plasma oxidation process, for example.

According to an embodiment of the present invention, the second conductive layer includes polysilicon, metal silicide or combinations thereof, for example.

According to an embodiment of the present invention, the method further includes forming two doped regions beside the second conductive layer.

The present invention further provides a method of fabricating a device. First, a substrate having at least one isolation structure is provided. Thereafter, a nitridation process is performed, so as to foam a nitride layer on the surface of the substrate and an oxynitirde layer on the surface of the isolation structure. Afterwards, an oxide layer is formed on the nitride layer and the oxynitride layer. Further, a densification process is performed, so as to oxidize the oxynitride layer on the surface of the isolation structure.

According to an embodiment of the present invention, the substrate includes silicon, polysilicon or amorphous silicon, for example.

According to an embodiment of the present invention, the nitridation process includes using remote plasma nitridation, decoupled plasma nitridation or microwave radical generator to generate nitrogen free radicals.

According to an embodiment of the present invention, the densification process includes a plasma oxidation process, for example.

In the method of the present invention, a nitridation process is performed to successfully enhance the dielectric constant in the active area between the isolation structures, and then a densification process is performed to oxidize the leakage path on the surface of the isolation structures. Thus, a leakage problem of the conventional device is avoided, and the reliability and performance of the device are enhanced.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A to 1F are schematic top views illustrating a method of fabricating a device according to an embodiment of the present invention.

FIGS. 2A to 2F are schematic cross-sectional views taken along the line I-I′ in FIGS. 1A to 1F.

FIGS. 3A to 3B are schematic cross-sectional views illustrating a method of fabricating a device according to an embodiment of the present invention.

### DESCRIPTION OF EMBODIMENTS

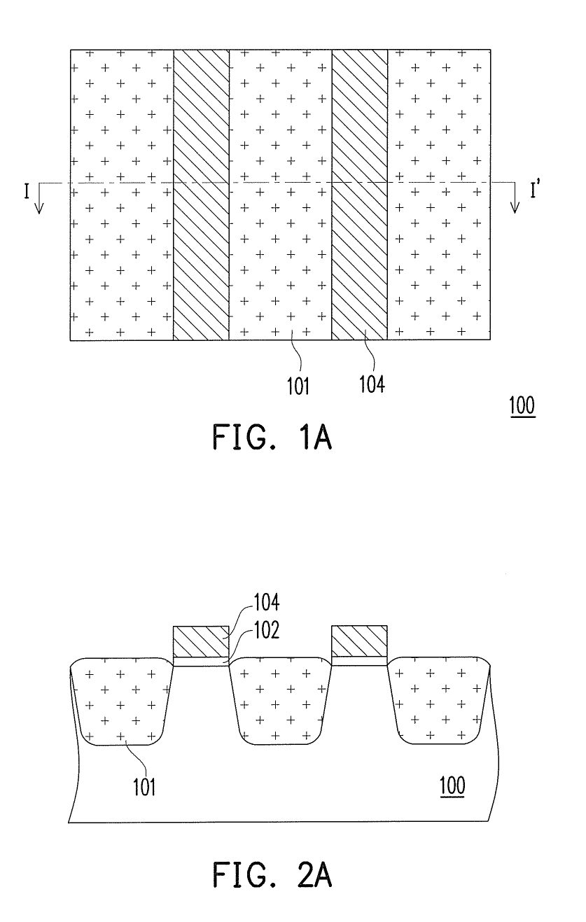

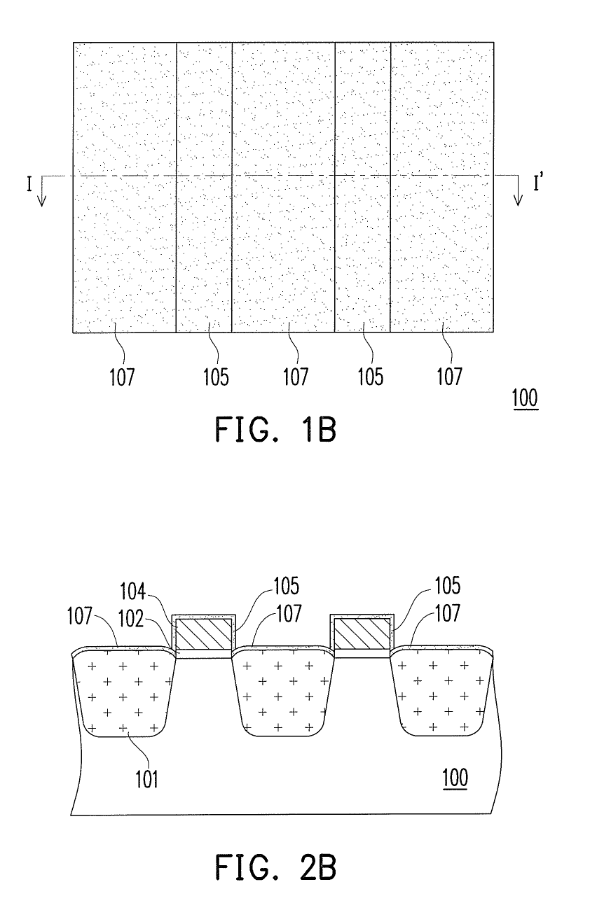

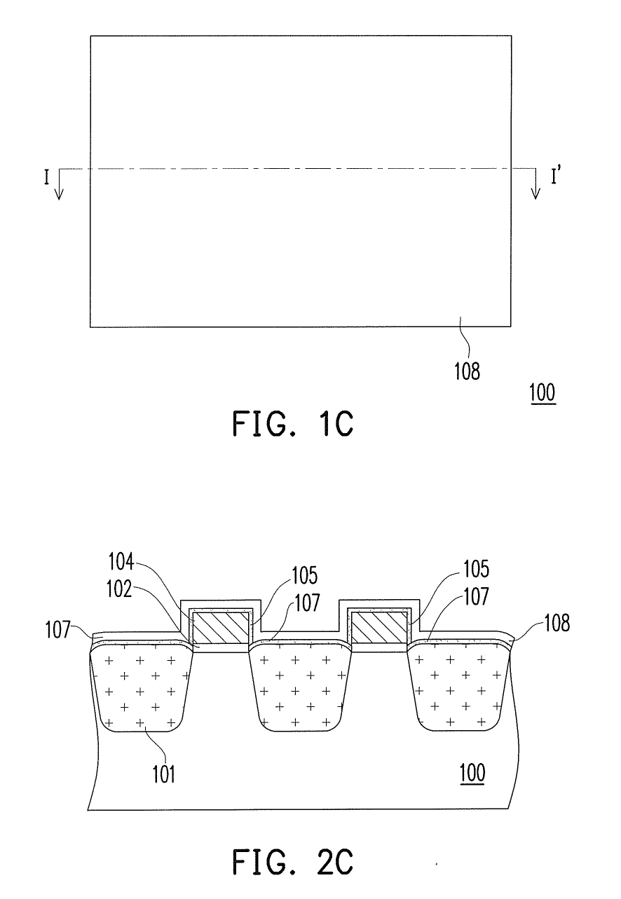

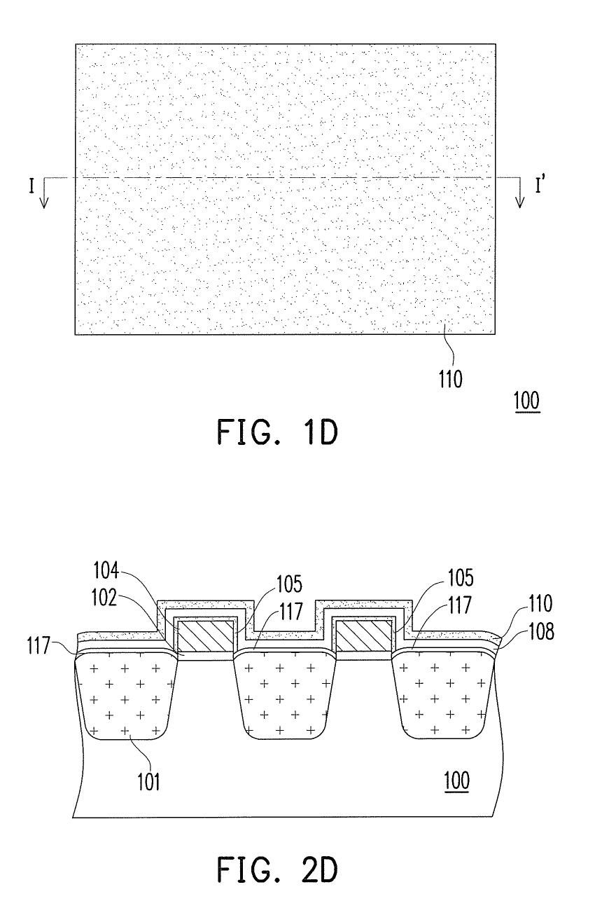

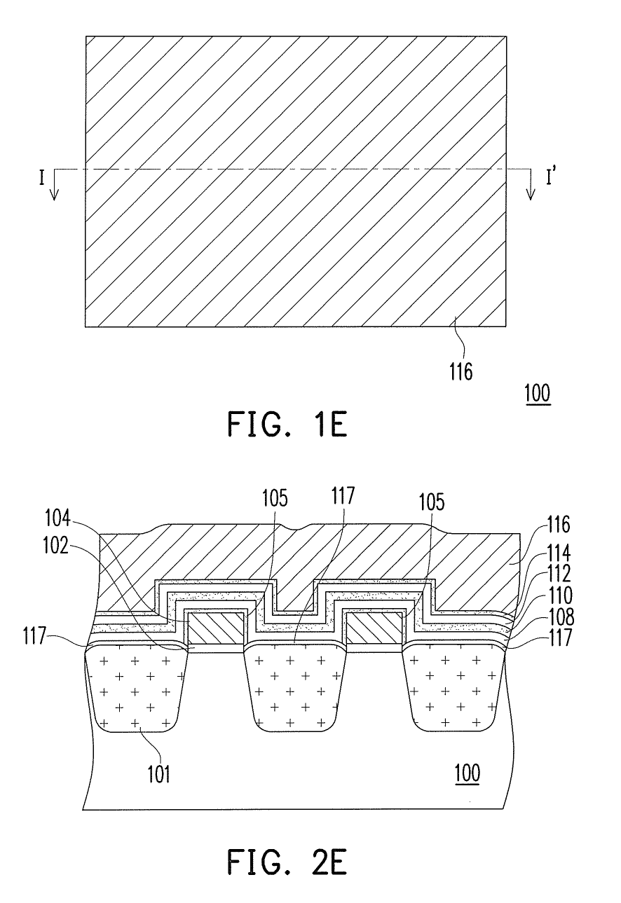

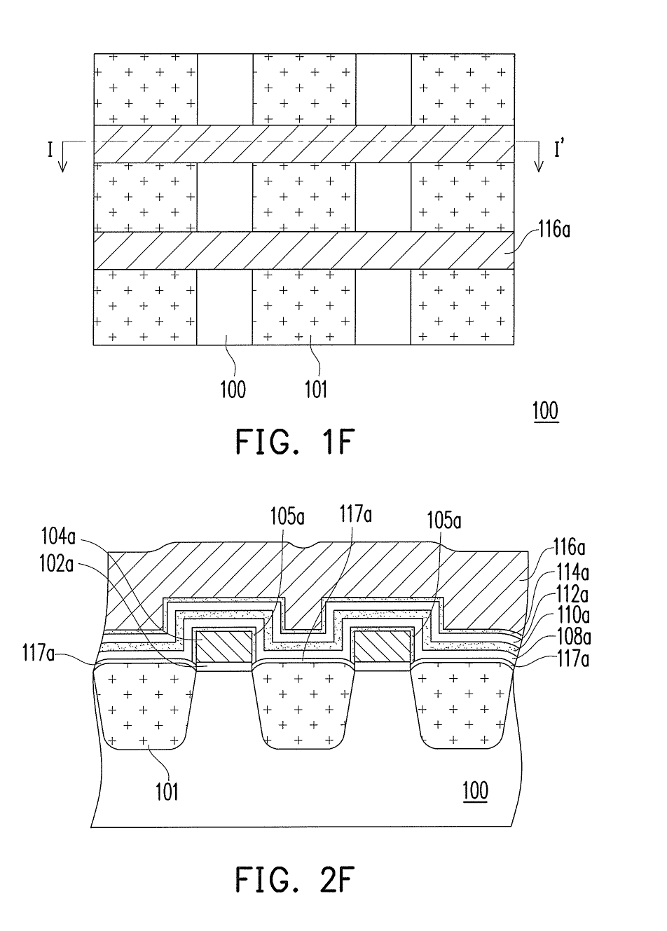

FIGS. 1A to 1F are schematic top views illustrating a method of fabricating a device according to an embodiment of the present invention. FIGS. 2A to 2F are schematic cross-sectional views taken along the line I-I′ in FIGS. 1A to 1F.

Referring to FIGS. 1A and 2A, a substrate 100 is provided, and at least two isolation structures 101 have been formed in the substrate 100. In an embodiment, the isolation structures 101 are shallow trench isolation (STI) structures disposed in parallel in the substrate 100. The substrate 100 includes a semiconductor substrate, and the material thereof includes silicon, polysilicon or amorphous silicon, for example. Thereafter, an oxide layer 102 and a conductive layer 104 are sequentially formed on the substrate 100 between the isolation structures 101. The oxide layer 102 includes silicon oxide, for example. The conductive layer 104 includes polysilicon, for example. The method of forming the oxide layer 102 and the conductive layer 104 includes forming an oxide material layer (not shown) and a conductive material layer (not shown) to cover the substrate 100, and then removing a portion of the oxide material layer and a portion of the conductive material layer.

Referring to FIGS. 1B and 2B, a first nitridation process is performed, so as to form a nitride layer 105 on the surface of the conductive layer 104 and an oxynitirde layer 107 on the surface of the isolation structures 101. The nitride layer 105 includes silicon nitride, for example. The oxynitride layer includes silicon oxynitride, for example. The first nitridation process nitridizes the surface of the wafer by using nitrogen free radicals, and remote plasma nitridation (RPN), decoupled plasma nitridation (DPN) or microwave radical generator (MRG) is used to generate nitrogen free radicals, for example.

Referring to FIGS. 1C and 2C, an oxide layer 108 is formed on the nitride layer 105 and the oxynitride layer 107. The oxide layer 108 includes silicon oxide, for example. In an embodiment, the oxide layer 108 is a high-temperature oxide (HTO) layer formed through a chemical vapor deoposition (CVD) process, for example.

Referring to FIGS. 1D and 2D, a densification process is performed, so as to oxidize the oxynitride layer 107 on the surface of the isolation structures 101. The densification process is a plasma oxidation process, and the parameters thereof include an Ar flow of about 1980 sccm, an oxygen flow of about 20 sccm, a pressure of about 200 Pa and a plasma power of about 4000 W, for example. In this step, oxygen passes through the oxide layer 108 and reacts with the oxynitride layer 107 on the surface of the isolation structures 101, so that the oxynitride layer 107 is oxidized to form an oxide layer 117. It is for sure that oxygen also passes through the oxide layer 108 to contact with the nitride layer 105 on the surface of the conductive layer 104. However, due to the oxidation rate of the nitride layer 105 is much less than that of the oxynitride layer 107, so that the nitride layer 105 is not oxidized to form an oxide layer.

Afterwards, a nitride layer 110 is formed on the oxide layer 108. The nitride layer 110 includes silicon nitride, and the forming method thereof includes performing a CVD process, for example.

Referring to FIGS. 1E and 2E, an oxide layer 112 is formed on the nitride layer 110. The oxide layer 112 includes silicon oxide, and the forming method thereof includes performing a CVD process or an in-situ steam generation (ISSG) process, for example. Thereafter, a second nitridation process is performed, so as to form a nitride layer 114 on the surface of the oxide layer 112. The nitride layer 112 includes silicon oxynitride, for example. The second nitridation process is the same as the first nitridation process. The second nitridation process nitridizes the surface of the wafer by using nitrogen free radicals, and remote plasma nitridation (RPN), decoupled plasma nitridation (DPN) or microwave radical generator (MRG) is used to generate nitrogen free radicals, for example. Afterwards, a conductive layer 116 is formed on the nitride layer 114. The conductive layer 116 includes polysilicon, metal silicide or combinations thereof. The method of forming the conductive layer 116 includes performing a CVD process.

Referring to FIGS. 1F and 2F, the nitride layer 105, the oxide layer 117, the oxide layer 108, the nitride layer 110, the oxide layer 112, the nitride layer 114 and the conductive layer 116 are patterned, so as to form a nitride layer 105a, an oxide layer 117a, an oxide layer 108a, a nitride layer 110a, an oxide layer 112a, a nitride layer 114a and a conductive layer 116a, all of which cross the isolation structures 101. During the patterning process, a portion of the oxide layer 102 and a portion of the conductive layer 104 are also removed simultaneously to form an oxide layer 102a and a conductive layer 104a. Thereafter, two doped regions (not shown) are formed beside the conductive layer 116a. The method of fabricating the device of the present invention is then completed.

When the structure depicted in FIG. 2F is applicable to a non-volatile memory, the oxide layer 102a serves as a tunnel dielectric layer, the conductive layer 104a serves as a floating gate and the conductive layer 116a serves as a control gate. Further, the nitride layer 105a, the oxide layer 108a, the nitride layer 110a, the oxide layer 112a and the nitride layer 114a form an inter-gate dielectric layer having an N-ONO-N structure, which can enhance the dielectric constant k and the gate coupling ratio at the same effective oxide thickness of the inter-gate dielectric layer.

It is noted that the densification process of the present invention successfully oxidizes the oxynitride layer 107 on the isolation structures 101, so that currents cannot flow between the adjacent floating gates (i.e. conductive layer 104a) via the oxynitride layer 107 on the isolation structures 101. That is, a leakage problem does not occur in the device fabricated based on the method of the present invention. Thus, the reliability and the charge retention ability are enhanced, and the operation speed of the device is significantly increased.

It is appreciated by persons skilled in the art that the present invention is not limited to be applicable to the non-volatile memory only. Generally speaking, the present invention can be applicable to all the processes in which the dielectric constant k is enhanced in the active area between the isolation structures, and a leakage problem does not occur between the adjacent active areas.

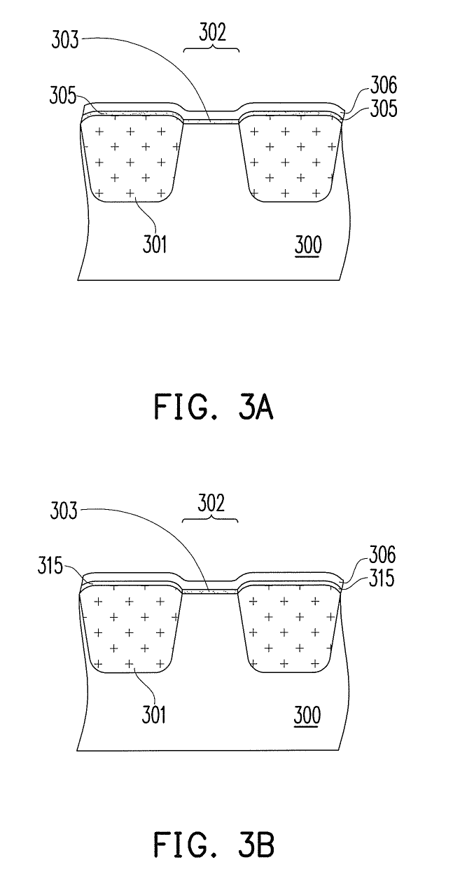

FIGS. 3A to 3B are schematic cross-sectional views illustrating a method of fabricating a device according to an embodiment of the present invention.

Referring to FIG. 3A, a substrate 300 is provided. At least two isolation structures 301 have been formed in the substrate 300, and an active area 302 is disposed between the isolation structures 301. The substrate 300 includes a semiconductor substrate, and the material thereof includes silicon, polysilicon or amorphous silicon, for example. Thereafter, a nitridation process is performed, so as to form a nitride layer 303 on the surface of the substrate 300 in the active region 302 and an oxynitride layer 305 on the surface of the isolation structures 301. The nitride layer 303 includes silicon nitride, for example. The oxynitride layer 305 includes silicon oxynitride, for example. The nitridation process includes nitridizes the surface of the wafer by using nitrogen free radicals, and remote plasma nitridation (RPN), decoupled plasma nitridation (DPN) or microwave radical generator (MRG) is used to generate nitrogen free radicals. Afterwards, an oxide layer 306 is formed on the nitride layer 303 and the oxynitride layer 305. The oxide layer 306 includes silicon oxide, and the forming method thereof includes performing a CVD process, for example.

Referring to FIG. 3B, a densification process is performed to the oxide layer 306, so as to oxidize the oxynitride layer 305 on the surface of the isolation structures 301 to form an oxide layer 315. The densification process is a plasma oxidation process, for example.

In summary, in the present invention, a nitridation process is performed to successfully enhance the dielectric constant in the active area between the isolation structures, and then a densification process is performed to oxidize the leakage path on the surface of the isolation structures. Thus, in the device fabricated based on the method of the present invention, a leakage problem can be avoided under the condition of enhancing the gate coupling rate, so that the reliability and the charge retention ability are enhanced, and the operation speed of the device is significantly increased.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

1. A method of fabricating a device, comprising:
providing a substrate, the substrate having at least two isolation structures;
forming a first oxide layer and a first conductive layer sequentially on the substrate between the isolation structures;
performing a first nitridation process, so as to form a first nitride layer on a surface of the first conductive layer and a first oxynitride layer on a surface of the isolation structures;
forming a second oxide layer on the first nitride layer and the first oxynitride layer;
performing a densification process, so as to oxidize the first oxynitride layer on the surface of the isolation structures;
forming a second nitride layer on the second oxide layer;
forming a third oxide layer on the second nitride layer;
performing a second nitridation process, so as to form a third nitride layer on a surface of the third oxide layer; and
forming a second conductive layer on the third nitride layer.

2. The method of claim 1, wherein the first conductive layer comprises polysilicon.

3. The method of claim 1, wherein the first nitridation process and the second nitridation process comprise using remote plasma nitridation, decoupled plasma nitridation or microwave radical generator to generate nitrogen free radicals.

4. The method of claim 1, wherein the densification process comprises a plasma oxidation process.

5. The method of claim 1, wherein the second conductive layer comprises polysilicon, metal silicide or combinations thereof.

6. The method of claim 1, further comprising forming two doped regions beside the second conductive layer.

7. A method of fabricating a device, comprising:
providing a substrate, the substrate having at least one isolation structure;
performing a nitridation process, so as to form a nitride layer on a surface of the substrate and an oxynitirde layer on a surface of the isolation structure;
forming an oxide layer on the nitride layer and the oxynitride layer; and
performing a densification process, so as to oxidize the oxynitride layer on the surface of the isolation structure.

8. The method of claim 7, wherein the substrate comprises silicon, polysilicon or amorphous silicon.

9. The method of claim 7, wherein the nitridation process comprises using remote plasma nitridation, decoupled plasma nitridation or microwave radical generator to generate nitrogen free radicals.

10. The method of claim 7, wherein the densification process comprises a plasma oxidation process.
